(19) United States
(12) Patent Application Publication
(10) Pub. No.: US 2014/0248439 A1
(43) Pub. Date: Sep. 4, 2014

(54) PATTERN FORMATION METHOD

(71) Applicant: KABUSHIKI KAISHA TOSHIBA, Tokyo (JP)

(72) Inventors: Hironobu SATO, Tsukuba-Shi (JP); Yuriko SEINO, Tokyo (JP); Masahiro KANNO, Yokohama-Shi (JP); Hirokazu KATO, Kariya-Shi (JP); Katsutoshi KOBAYASHI, Tokyo (JP); Hiroki YONEMITSU, Kawasaki-shi (JP); Ayako KAWANISHI, Yokohama-Shi (JP)

(73) Assignee: KABUSHIKI KAISHA TOSHIBA, Tokyo (JP)

(21) Appl. No.: 13/956,857

(22) Filed: Aug. 1, 2013

(30) Foreign Application Priority Data
Mar. 1, 2013 (JP) 2013-040924

(51) Int. Cl. H01L 21/02

(52) U.S. Cl. CPC H01L 21/02104
USPC 427/510

(57) ABSTRACT

According to one embodiment, a pattern formation method includes coating a polymer material on a film to be processed, the polymer material having a first segment and a second segment, the second segment containing a functional group that causes a cross-linking reaction, performing microphase separation of the polymer material to form a self-assembly pattern having a first polymer portion that contains the first segment and a second polymer portion that contains the second segment, performing irradiation with energy rays toward the self-assembly pattern in a cooling state; and selectively removing the first polymer portion.

### CROSS REFERENCE TO RELATED APPLICATION

This application is based upon and claims benefit of priority from the Japanese Patent Application No. 2013-40924, filed on Mar. 1, 2013, the entire contents of which are incorporated herein by reference.

### FIELD

Embodiments described herein relate generally to a pattern forming method.

### BACKGROUND

As lithography techniques in a process of manufacturing semiconductor elements, there are known a double patterning technique by ArF liquid immersion exposure, an EUV lithography, a nanoimprint, and the like. As patterns are finer, conventional lithography techniques had various problems such as increased cost and reduced throughput.

Under such circumstances, directed self-assembly (DSA) is expected to be applied to the lithography techniques. Since self-assembly is caused by a spontaneous behavior of energy stabilization, patterns having a high dimensional accuracy can be formed. In particular, by a technique using microphase separation of a high molecular weight block copolymer, a periodic structure having a variety of shapes with a size ranging from several to several hundreds of nm can be formed by a simple process of coating and annealing. By changing the form to a sphere, a cylinder, a lamella and the like depending on a composition ratio of blocks of the high molecular weight block copolymer, and changing the size depending on a molecular weight, there can be formed a dot pattern, a hole or pillar pattern, a line pattern and the like each having various dimensions.

In order to form fine patterns with self-assembly by a high molecular weight block copolymer, a material to be used needs to have a high χ parameter, which indicates a likeliness of phase separation, and a small molecular weight. However, when such a material is used, there has been a problem that fluctuations due to molecular vibration cause indistinct phase separation interface, thereby worsening roughness of the edge of a pattern.

### BRIEF DESCRIPTION OF THE DRAWINGS

FIG. 1 is a process cross sectional diagram depicting the pattern formation method according to the present embodiment;

FIG. 2 is a process cross sectional diagram subsequent to FIG. 1;

FIG. 3 is a process cross sectional diagram subsequent to FIG. 2;

FIG, 4 is a process cross sectional diagram subsequent to FIG. 3;

FIG. 5 is a process cross sectional diagram subsequent to FIG. 4;

FIG. 6 is a process cross sectional diagram subsequent to FIG. 5; and

FIG. 7 is a process cross sectional diagram depicting the pattern formation method according to a variation.

### DETAILED DESCRIPTION

According to one embodiment, a pattern formation method includes coating a polymer material on a film to be processed, the polymer material having a first segment and a second segment, the second segment containing a functional group that causes a cross-linking reaction, performing microphase separation of the polymer material to form a self-assembly pattern having a first polymer portion that contains the first segment and a second polymer portion that contains the second segment, performing irradiation with energy rays toward the self-assembly pattern in a cooling state; and selectively removing the first polymer portion.

With reference to FIGS. 1 to 6, the pattern formation method according to the present embodiment will be described.

First, as depicted in FIG. 1, a chemical pre-patterns is formed on a substrate (a film to be processed) 101. Specifically, an antireflection film 102 is formed on the substrate 101, and then a neutralization film 103 and a resist film (not shown) are sequentially formed on the antireflection film 102. The neutralization film 103 has an equal affinity to all elements constituting a self-assembly material which will be coated in a process performed later. When the reflection from the substrate 101 is sufficiently low, the antireflection film 102 may be omitted.

Next, a desired pattern is formed on the resist film by a lithography treatment. Then, the neutralization film 103 is etched by using the formed resist pattern as a mask, thereby to transfer the resist pattern to the neutralization film 103. Then, the resist film is removed. Accordingly, a chemical pre-patterns including the antireflection film 102 and the neutralization film 103 as depicted in FIG. 1 is obtained.

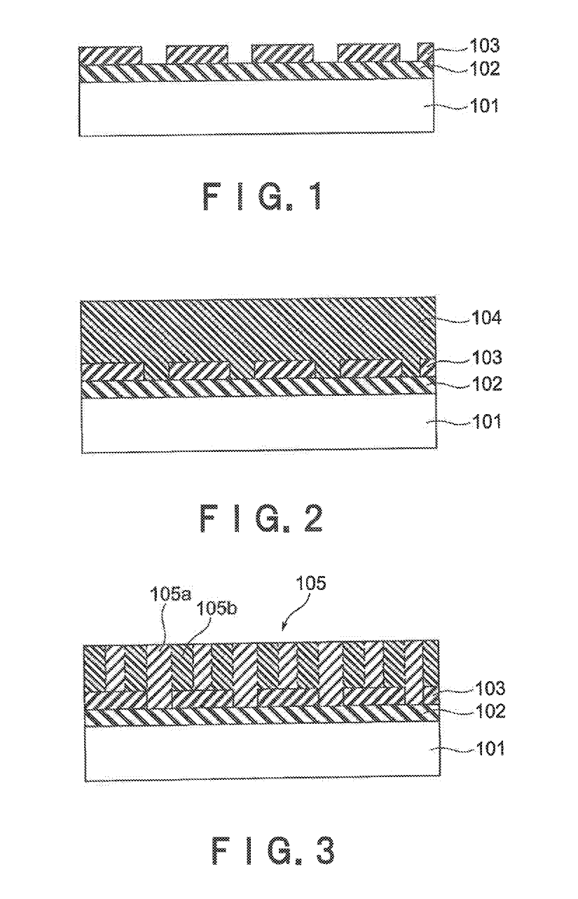

Next, as depicted in FIG. 2, a self-assembly material 104 is coated on the antireflection film 102 and the neutralization film 103. As a self-assembly material for coating, for example, a diblock copolymer including a first segment and a second segment both covalently bound with each other is used. As the diblock copolymer, for example, a block copolymer of polystyrene (PS) and polymethyl methacrylate (PMMA) can be used. By adjusting the composition of PS and PMMA, phase separation results in lamellar structure in some cases and cylinder structure in some cases.

In the present embodiment, one of the first segment and the second segment of the self-assembly material 104 has a functional group that causes a cross-linking reaction. Examples of such a functional group include an acryloyl group, a methacryl group, an epoxy group, an alicyclic epoxy group, a glycidyl group, an oxetanyl group, a cross-linkable silicon group, an alkoxysilyl group (a methoxy group, an ethoxy group, an n-propoxy group, an iso-propoxy group, an n-butoxy group, a sec-butoxy group, a tert-butoxy group), an acetoxysilyl group, a phenoxysilyl group, a silanol group, a chlorosilyl group, a vinyl group, a vinyloxy group, an imide group, a maleimide group, and a phthalimide group.

Next, as depicted in FIG. 3, the self-assembly material 104 is subjected to microphase separation. As a result of microphase separation, there is formed a self-assembly pattern 105 including a first polymer portion 105a that has the first segment and a second polymer portion 105b that has the second segment.

For example, when the self-assembly material 104 is a block copolymer of polystyrene (PS) and polymethyl methacrylate (PMMA), and the antireflection film 102 is a spin-on glass (SOG) film, SOG has a high affinity to PMMA. Therefore, when microphase separation is developed, a PMMA phase is selectively formed on the antireflection film 102. In brief, the first polymer portion 105a corresponds to PMMA, and the second polymer portion 105b corresponds to PS.

At this time, molecular vibration causes a phase separation interface (an interface between the first polymer portion 105a and the second polymer portion 105b) to become blurred and indistinct,

Next, the substrate 101 is placed in a cooling atmosphere and subjected to a cooling annealing treatment. For example, liquid nitrogen is used for the cooling annealing treatment. The cooling atmosphere is an atmosphere having a temperature lower than that when the self-assembly material 104 is subjected to microphase separation depicted in FIG. 3. An example of the cooling atmosphere is an atmosphere not higher than 0° C. By maintaining the self-assembly pattern 105 in such a low temperature state, molecular vibration is reduced, and the phase separation interface becomes distinct as depicted in FIG. 4.

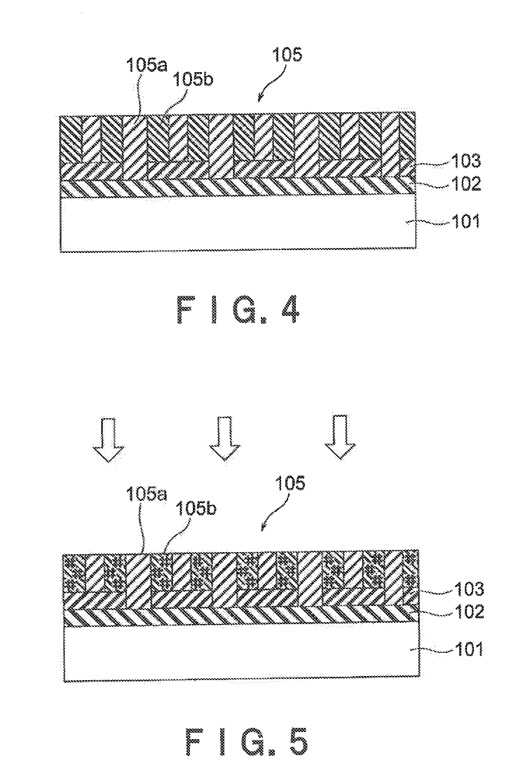

Next, as depicted in FIG. 5, the self-assembly pattern 105 is irradiated with energy rays such as ultraviolet rays to cause a cross-linking reaction. A cross-linking reaction is initiated in the first polymer portion 105a or the second polymer portion 105b having the first segment or the second segment, which contains the above-mentioned functional group. FIG. 5 depicts an example of initiating a cross-linking reaction in the second polymer portion 105b.

A cross-linking reaction allows for an increase in molecular weight. Therefore, even when the substrate 101 is placed back at normal temperature, the first polymer portion 105a or the second polymer portion 105b still has a high molecular weight. Thus, molecular vibration is inhibited, and the distinct phase separation interface is retained.

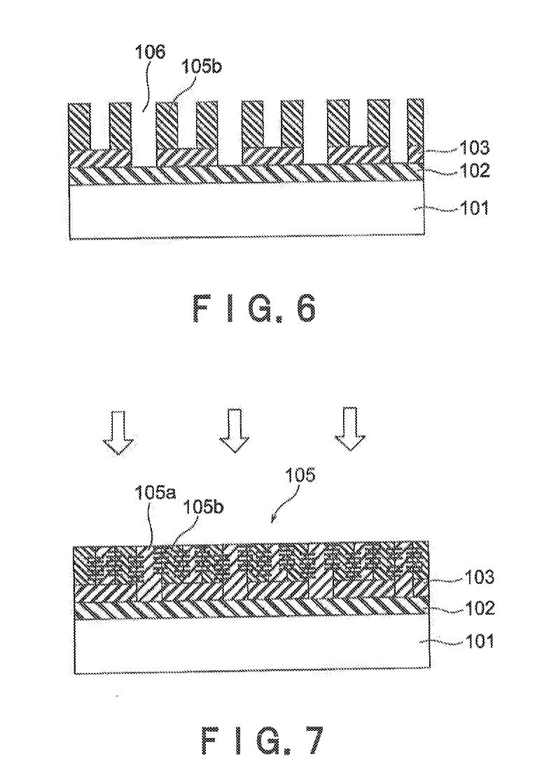

Next, a polymer portion in which a cross-linking reaction is not initiated, of the first polymer portion 105a and the second polymer portion 105b, is selectively removed. For example, when polystyrene (PS) has the above-described functional group and a cross-linking reaction was initiated in the second polymer portion 105b, the first polymer portion 105a is selectively removed to form a hole pattern 106 as depicted in FIG. 6.

Subsequently, an etching treatment is performed by using the second polymer portion 105b as a mask, thereby to transfer a pattern to the substrate (the film to be processed) 101.

Thus, according to the present embodiment, either a first segment or a second segment of a self-assembly material has a functional group that causes initiation of a cross-linking reaction, and a cross-linking reaction is initiated in a state of cooling a self-assembly pattern and obtaining a distinct phase separation interface. Therefore, even after returning to a state of normal temperature, a distinct phase separation interface can be obtained.

Furthermore, roughness on the pattern edge of the self-assembly pattern can be inhibited from worsening, and variations of a pattern shape to be transferred to a film to be processed can be suppressed.

In the above-mentioned embodiment, one of the first segment and the second segment of the self-assembly material 104 has a functional group that causes a cross-linking reaction. However, both the first segment and the second segment may have such functional groups,

When such a self-assembly material is used, irradiation with energy rays toward the self-assembly material in a cooling state following to microphase separation causes initiation of a cross-linking reaction between different segments (between the first polymer portion 105a and the second polymer portion 105b) as depicted in FIG. 7. In a subsequent process, the first polymer portion 105a may be selectively removed, or the second polymer portion 105b may be selectively removed.

In the above-mentioned embodiment, a block copolymer of polystyrene (PS) and polymethyl methacrylate (PMMA) is used as the self-assembly material 104. However, other materials such as a block copolymer of polystyrene (PS) and polydimethyl siloxane (PDMS) may be used.

Also, in the above-mentioned embodiment, a photo acid-generating agent for promoting a cross-linking reaction in the self-assembly material 104 may be added.

In the above-mentioned embodiment, a self-assembly pattern is formed using a chemical pre-patterns. However, physical pre-patterns having a concavo-convex structure may be used. As the physical pre-patterns, a resist pattern or a stacked structure of a spin-on carbon (SOC) film and an SOG film can be used. A self-assembly material is embedded (filled) in a concave portion of the physical pre-patterns.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A pattern formation method, comprising:
coating a polymer material on a film to be processed, the polymer material having a first segment and a second segment, the second segment containing a functional group that causes a cross-linking reaction;
performing microphase separation of the polymer material to form a self-assembly pattern having a first polymer portion that contains the first segment and a second polymer portion that contains the second segment;
performing irradiation with energy rays toward the self-assembly pattern in a cooling state; and
selectively removing the first polymer portion,

2. The pattern formation method according to claim 1, wherein the polymer material contains a photo acid-generating agent.

3. The pattern formation method according to claim 1, wherein a crosslinking reaction is initiated in the second polymer portion by the irradiation with energy rays.

4. The pattern formation method according to claim 1, further comprising: performing microphase separation of the polymer material at a first temperature; and performing the irradiation with energy rays at a second temperature being lower than the first temperature.

5. The pattern formation method according to claim 4, wherein the second temperature is not higher than 0° C.

6. The pattern formation method according to claim 1, further comprising:
forming chemical pre-patterns on the Film to be processed; and
coating the polymer material on the chemical pre-patterns.

7. The pattern formation method according to claim 6, wherein the chemical pre-patterns includes:
an antireflection film disposed on the film to be processed; and
a neutralization film disposed on the antireflection film.

8. The pattern formation method according to claim 1, further comprising:
forming physical pre-patterns having a concavo-convex structure on the film to be processed; and
embedding the polymer material in a concave portion of the physical pre-patterns.

9. The pattern formation method according to claim 1, wherein the functional group is an acryloyl group, a methacryl group, an epoxy group, an alicyclic epoxy group, a glycidyl group, an oxetanyl group, a cross-linkable silicon group, an alkoxysilyl group, an acetoxysilyl group, a phenoxysilyl group, a silanol group, a chlorosilyl group, a vinyl group, a vinyloxy group, an imide group, a maleimide group, or a phthalimide group.

10. A pattern formation method, comprising:
coating a polymer material on a film to be processed, the polymer material having a first segment and a second segment, the first segment containing a functional group that causes a cross-linking reaction and the second segment containing a functional group that causes a cross-linking reaction;
performing microphase separation of the polymer material to form a self-assembly pattern having a first polymer portion that contains the first segment and a second polymer portion that contains the second segment;
performing irradiation with energy rays toward the self-assembly pattern in a cooling state; and
selectively removing the first polymer portion or the second polymer portion.

11. The pattern formation method according to claim 10, wherein the polymer material contains a photo acid-generating agent.

12. The pattern formation method according to claim 10, wherein a cross-linking reaction is initiated between the first polymer portion and the second polymer portion by the irradiation with energy rays.

13. The pattern formation method according to claim 10, further comprising: performing microphase separation of the polymer material at a first temperature; and performing the irradiation with energy rays at a second temperature being lower than the first temperature.

14. The pattern formation method according to claim 13, wherein the second temperature is not higher than 0° C.

15. The pattern formation method according to claim 10, further comprising:
forming chemical pre-patterns on the film to be processed; and
coating the polymer material on the chemical pre-patterns.

16. The pattern formation method according to claim 15, wherein the chemical pre-patterns includes:
an antireflection film disposed on the film to be processed; and
a neutralization film disposed on the antireflection film.

17. The pattern formation method according to claim 10, further comprising:
forming physical pre-patterns having a concavo-convex structure on the film to be processed; and
embedding the polymer material in a concave portion of the physical pre-patterns.

18. The pattern formation method according to claim 10, wherein the functional group is an acryloyl group, a methacryl group, an epoxy group, an alicyclic epoxy group, a glycidyl group, an oxetanyl group, a cross-linkable silicon group, an alkoxysilyl group, an acetoxysilyl group, a phenoxysilyl group, a silanol group, a chlorosilyl group, a vinyl group, a vinyloxy group, an imide group, a maleimide group, or a phthalimide group.
